(19) United States
(12) Patent Application Publication
(10) Pub. No.: US 2026/0101664 A1
(43) Pub. Date: Apr. 9, 2026

(54) DISPLAY DEVICE, METHOD OF MANUFACTURING THE SAME, AND ELECTRONIC DEVICE INCLUDING THE SAME

(71) Applicant: SAMSUNG DISPLAY CO., LTD., YONGIN-SI (KR)

(72) Inventors: Seonhye Kim, YONGIN-SI (KR); Minsu Kim, YONGIN-SI (KR)

(21) Appl. No.: 19/346,911

(22) Filed: Oct. 1, 2025

(30) Foreign Application Priority Data
Oct. 7, 2024 (KR) 10-2024-0135973

(51) Int. Cl. H10K 59/80; H10K 59/12

(52) U.S. Cl. CPC H10K 59/873; H10K 59/1201

(57) ABSTRACT

A display device includes a substrate including a display area and a non-display area proximate to the display area. A first dam is disposed in the non-display area. A second dam is disposed in the non-display area. An alignment mark is disposed between the first dam and the second dam and is provided as an opening in a metal layer. A planarization layer is disposed on the first dam, the second dam, and the alignment mark. An optical function layer is disposed on the planarization layer. An entire upper surface of the planarization layer overlapping the alignment mark adheres to an entire lower surface of the optical function layer disposed on the planarization layer.

### CROSS-REFERENCE TO RELATED APPLICATION

This application claims priority under 35 U.S.C. §119 to Korean Patent Application No. 10-2024-0135973, filed on October 7, 2024, in the Korean Intellectual Property Office, the disclosure of which is incorporated by reference herein in its entirety.

### TECHNICAL FIELD

The present disclosure relates to a display device and, more particularly, to a display device including an alignment mark between dams and a method of manufacturing the display device.

### DISCUSSION OF THE RELATED ART

Display devices are used to visually present data and can vary in size depending on their application. For example, display devices may be integrated into small products, such as mobile phones, or larger products, such as televisions.

These devices include a plurality of pixels that receive electrical signals and emit light to display images to a user. Each of the pixels includes a display element, and for example, an organic light-emitting diode display device includes an organic light-emitting diode (OLED) as a display element. Generally, in OLED display device, a thin-film transistor and an OLED are formed on a substrate, and the OLED operates by emitting light.

Recently, as the uses of display devices have become more diverse, various designs for improving the quality of display devices have been attempted.

### SUMMARY

A display device includes a substrate including a display area and a non-display area proximate to the display area. A first dam is disposed in the non-display area. A second dam is disposed in the non-display area. An alignment mark is disposed between the first dam and the second dam and is provided as an opening in a metal layer. A planarization layer is disposed on the first dam, the second dam, and the alignment mark. An optical function layer is disposed on the planarization layer. An entire upper surface of the planarization layer overlapping the alignment mark is adhered to an entire lower surface of the optical function layer disposed on the planarization layer.

The entire upper surface of the planarization layer overlapping the alignment mark may be flat.

The display device may further include a light blocker disposed on the first dam and the second dam.

The light blocker may have an opening overlapping the alignment mark.

The light blocker may have an opening overlapping the opening of the metal layer.

The light blocker may be disposed on an upper surface of the first dam.

The light blocker may be disposed on an upper surface of the second dam.

The first dam and the second dam may each include an organic insulating material and/or an inorganic insulating material.

The display device may further include a thin-film transistor, which is disposed in the display area and includes a semiconductor layer, a gate electrode, a source electrode, and a drain electrode.

The source electrode or the drain electrode may include a same material as the metal layer.

A method of manufacturing a display device includes forming a metal layer on a substrate. An alignment mark is formed by forming an opening in the metal layer. An alignment mark is formed between a first dam and a second dam. A light blocker is formed on the first dam and the second dam. An opening is formed in the light blocker, the opening overlapping the alignment mark. A first planarization layer is formed on the alignment mark and the light blocker. A second planarization layer is formed on the first planarization layer, the second planarization layer overlapping the alignment mark.

At least a portion of an upper surface of the first planarization layer overlapping the alignment mark may be concave.

An upper surface of the second planarization layer overlapping the alignment mark may be flat.

The method may further include forming an optical function layer on the second planarization layer.

An entire upper surface of the second planarization layer may be adhered to an entire lower surface of the optical function layer.

The light blocker may be disposed on an upper surface of the first dam.

The light blocker may be disposed on an upper surface of the second dam.

The method may further include forming a thin-film transistor, which is disposed on the substrate and includes a semiconductor layer, a gate electrode, a source electrode, and a drain electrode.

The source electrode or the drain electrode may include a same material as the metal layer.

The opening of the light blocker may overlap the opening of the metal layer.

An electronic device includes a substrate including a display area and a non-display area proximate to the display area. A first dam is disposed in the non-display area. A second dam is disposed in the non-display area. An alignment mark is disposed between the first dam and the second dam and is provided as an opening in a metal layer. A planarization layer is disposed on the first dam, the second dam, and the alignment mark. An optical function layer is disposed on the planarization layer. An entire upper surface of the planarization layer overlapping the alignment mark is adhered to an entire lower surface of the optical function layer disposed on the planarization layer.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a plan view of a display device according to an embodiment;

FIG. 2 is a schematic cross-sectional view of the display device taken along line I-I' of FIG. 1;

FIG. 3 is a schematic enlarged plan view of area A of FIG. 1;

FIG. 4 is a schematic cross-sectional view of the display device taken along line II-II' of FIG. 3;

FIGS. 5 to 11 are schematic cross-sectional views illustrating a method of manufacturing a display device;

FIG. 12 is a block diagram of an electronic device according to an embodiment; and

FIG. 13 is a schematic diagram of an electronic device according to various embodiments.

### DETAILED DESCRIPTION

Reference will now be made in detail to embodiments, examples of which are illustrated in the accompanying drawings, wherein like reference numerals may refer to like elements throughout the specification and the drawings. In this regard, the present embodiments may have different forms and should not necessarily be construed as being limited to the descriptions set forth herein. Accordingly, the embodiments below are described by referring to the figures, to explain aspects of the present description. As used herein, the term "and/or" includes any and all combinations of one or more of the associated listed items. Throughout the disclosure, the expression "at least one of a, b or c" indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. The attached drawings for illustrating one or more embodiments are referred to in order to gain a sufficient understanding, the merits thereof, and the objectives accomplished by the implementation. However, the embodiments may have different forms and should not necessarily be construed as being limited to the descriptions set forth herein.

To the extent that an element is not described in detail with respect to this figure, it may be understood that the element is at least similar to a corresponding element that has been described elsewhere within the present disclosure.

It will be understood that although the terms "first," "second," etc. may be used herein to describe various components, these components should not necessarily be limited by these terms. These components are used to distinguish one component from another.

As used herein, the singular forms "a," "an," and "the" are intended to include the plural forms as well, unless the context clearly indicates otherwise.

It will be further understood that the terms "includes", "has", "including", and/or "having" used herein specify the presence of stated features or components, but do not preclude the presence or addition of one or more other features or components.

It will be understood that when a layer, region, or component is referred to as being "formed on" another layer, region, or component, it can be directly or indirectly formed on the other layer, region, or component. For example, intervening layers, regions, or components may be present.

While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

When a certain embodiment may be implemented differently, a specific process order may be performed differently from the described order. For example, two consecutively described processes may be performed substantially at the same time or performed in an order opposite to the described order.

In the present specification, an expression such as "A and/or B" indicates A, B, or A and B. Also, an expression such as "at least one of A and B" indicates A, B, or A and B.

In the following embodiments, when layers, regions, or components are connected to each other, the layers, the regions, or the components may be directly connected to each other, or another layer, another region, or another component may be interposed between the layers, the regions, or the components and thus the layers, the regions, or the components may be indirectly connected to each other. For example, in the following embodiments, when layers, regions, or components are electrically connected to each other, the layers, the regions, or the components may be directly electrically connected to each other, or another layer, another region, or another component may be interposed between the layers, the regions, or the components and thus the layers, the regions, or the components may be indirectly electrically connected to each other.

The x-axis, the y-axis and the z-axis are not necessarily limited to three axes of the Cartesian coordinate system, and may be interpreted in a broader sense. For example, the x-axis, the y-axis, and the z-axis may be perpendicular to one another, or may represent different directions that are not perpendicular to one another.

Exemplary embodiments of the present invention relate to an improved structural design and manufacturing process of a display device to enhance reliability and optical performance. The display device includes a planarization layer and an optical function layer, both of which are carefully structured to prevent defects such as air bubbles that could degrade display quality.

One key innovation is the incorporation of alignment marks in the non-display area of the device. These alignment marks, formed as openings in a metal layer, play a crucial role in the manufacturing precision of the display. To maintain the visibility and effectiveness of these alignment marks, the design includes a planarization layer with a flat surface that ensures full adhesion with the optical function layer. This prevents air bubbles or voids from forming, which could otherwise impact the quality and reliability of the display panel.

Additionally, a multi-layer dam structure surrounding the alignment mark may be used/. This structure serves multiple functions such as containing the encapsulation layer to prevent overflow and supporting manufacturing masks used during processing. A light blocker is also incorporated to enhance contrast and visibility by reducing external light interference.

The manufacturing method includes a dual-layer planarization process, where an initial planarization layer is applied but may have surface irregularities, which are then corrected by a second planarization layer. This ensures that the optical function layer, such as a polarizing plate, adheres properly without defects. The display device may also be embodied as an electronic device.

Accordingly, embodiments of the present disclosure may provide a structural and manufacturing improvement aimed at enhancing the optical clarity, alignment precision, and reliability of modern display devices, particularly those using organic light-emitting diodes (OLEDs) and thin-film transistors (TFTs).

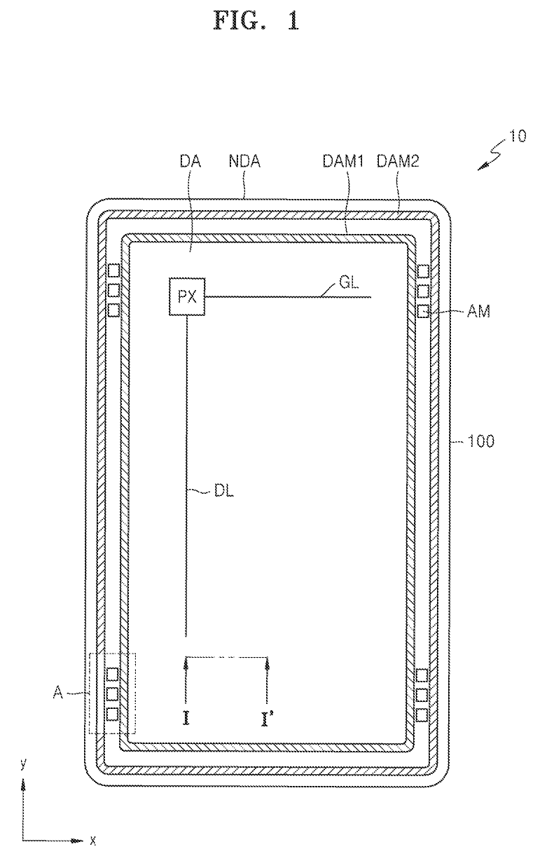

FIG. 1 is a plan view of a display device 10 according to an embodiment.

Referring to FIG. 1, the display device 10 may include a substrate 100. The substrate 100 may include a display area DA and a non-display area NDA. The display area DA may be an area that displays an image. The non-display area NDA may surround at least a portion of the display area DA. For example, the non-display area NDA may be proximate to one or more sides of the display area DA. The non-display area NDA may be an area that does not display an image.

Pixels PX may be disposed entirely within in the display area DA. The pixels PX may emit light to display an image. In addition, wiring lines that are connected to the pixels PX and configured to transmit signals to the pixels PX may be disposed in the display area DA. For example, the wiring lines may include data lines DL configured to transmit data signals and gate lines GL configured to transmit gate signals.

At least one dam may be disposed in the non-display area NDA on the substrate 100. For example, a first dam DAM and a second dam DAM2 may be disposed in the non-display area NDA.

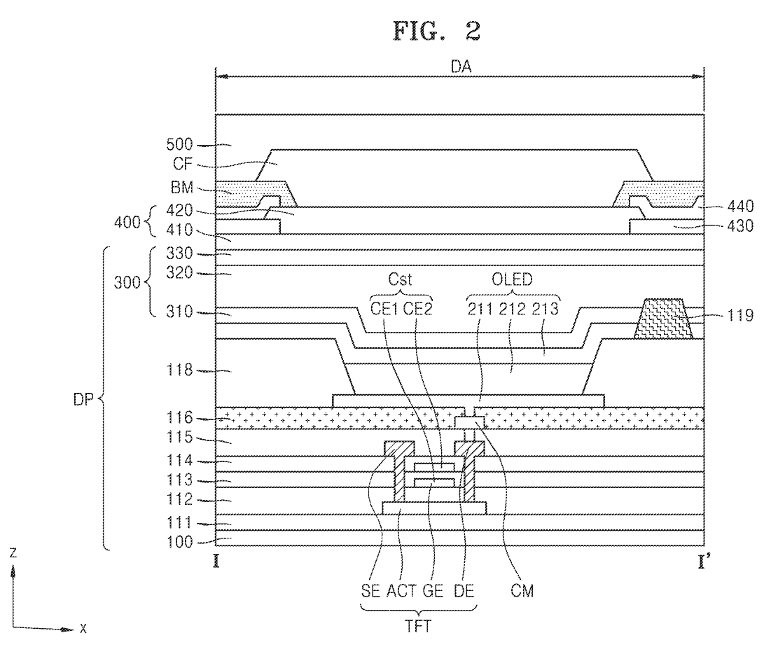

The first dam DAM1 may be disposed on the periphery of the display area DA. The first dam DAM1 may surround the display area DA. The first dam DAM1 may confine an organic encapsulation layer (for example, an organic encapsulation layer 320 in FIG. 2) disposed in the display area DA. For example, the first dam DAM1 may prevent the organic encapsulation layer from overflowing to the periphery of the non-display area NDA.

The second dam DAM2 may be disposed on the periphery of the display area DA. The second dam DAM2 may surround the first dam DAM1. The second dam DAM2 may support a mask positioned on the display device 10 during a process of manufacturing the display device 10. The mask might not directly contact a display panel included in the display device 10 through the second dam DAM2. However, the disclosure is not necessarily limited thereto.

Alignment marks AM may be disposed in the non-display area NDA. The alignment marks AM may be used during the manufacturing process. For example, the alignment marks AM may indicate the positions of components required for the process of manufacturing the display device 10. Although 24 alignment marks AM are shown in FIG. 1, this is an example, and the alignment marks AM may be variously disposed on the substrate 100 within a range where the components may be accurately positioned.

For example, the alignment marks AM may be disposed only on the side of the substrate 100. Alternatively, the alignment marks AM may be disposed only at each corner of the upper surface of the substrate 100. However, the disclosure is not necessarily limited thereto.

FIG. 2 is a schematic cross-sectional view of the display device 10 taken along line I-I' of FIG. 1.

Referring to FIGS. 1 and 2, the display device 10 may include a display panel DP, a touch layer TM, a light blocker BM, a color filter CF, and a planarization layer 500. In the display area DA, the display panel DP may include a substrate 100, a buffer layer 111, insulating layers 112, 113, 114, 115, 116, and 118, a thin-film transistor TFT, a data line DL, a connection electrode CM, an organic light-emitting diode OLED, and an encapsulation layer 300.

The buffer layer 111 may be disposed on the substrate 100. The buffer layer 111 may be disposed in the display area DA and the non-display area NDA. The buffer layer 111 may prevent metal atoms or other impurities from diffusing from the substrate 100 to a semiconductor layer ACT.

The thin-film transistor TFT may be disposed in the display area DA on the substrate 100. The thin-film transistor TFT may include an oxide layer (i.e., the semiconductor layer ACT), a gate electrode GE, a source electrode SE, and a drain electrode DE.

In the display area DA, the semiconductor layer ACT may be disposed on the buffer layer 111. The semiconductor layer ACT may be divided into a source region and a drain region, that are each doped with impurities, and a channel region between the source region and the drain region.

A first insulating layer 112 may be disposed on the buffer layer 111. In the display area DA, the first insulating layer 112 may cover the semiconductor layer ACT and may be continuously disposed on the substrate 100 (e.g., disposed as a continuous structure without breaks or interruptions). However, the embodiments according to the disclosure are not necessarily limited thereto. In an embodiment, the first insulating layer 112 may include an inorganic material.

In the display area DA, the gate electrode GE may be disposed on the first insulating layer 112. The gate electrode GE may overlap the channel region of the semiconductor layer ACT.

A second insulating layer 113 may be disposed on the first insulating layer 112. In addition, the second insulating layer 113 may be continuously disposed on the substrate 100 to cover the gate electrode GE. However, the embodiments according to the disclosure are not necessarily limited thereto. In an embodiment, the second insulating layer 113 may include an inorganic material.

In the display area DA, an upper electrode CE2 may be disposed on the second insulating layer 113. The upper electrode CE2 may be a capacitor electrode. A lower electrode CE1 may be disposed integrally with the gate electrode GE below the upper electrode CE2. The upper electrode CE2 and the lower electrode CE1 may form a capacitor Cst.

A third insulating layer 114 may be disposed on the second insulating layer 113. In addition, the third insulating layer 114 may cover the upper electrode CE2 and may be continuously disposed on the substrate 100. However, the disclosure is not necessarily limited thereto. In an embodiment, the third insulating layer 114 may include an inorganic material.

In the display area DA, the source electrode SE, the drain electrode DE, the data line DL, etc. may be disposed on the third insulating layer 114.

The source electrode SE may be connected to the source region of the semiconductor layer ACT through a contact hole formed in the first to third insulating layers 112, 113, and 114. The drain electrode DE may be connected to the drain region of the semiconductor layer ACT through a contact hole formed in the first to third insulating layers 112, 113, and 114.

In the display area DA, the fourth insulating layer 115 may be disposed on the third insulating layer 114. In addition, the fourth insulating layer 115 may be continuously disposed on the substrate 100 to cover the source electrode SE and the drain electrode DE. However, the disclosure is not necessarily limited thereto. In an embodiment, the fourth insulating layer 115 may include an organic material.

In the display area DA, the connection electrode CM may be disposed on the fourth insulating layer 115. The connection electrode CM may be connected to the drain electrode DE or the source electrode SE through a contact hole formed in the fourth insulating layer 115.

In the display area DA, the fifth insulating layer 116 may be disposed on the fourth insulating layer 115. The fifth insulating layer 116 may cover the connection electrode CM and may be continuously disposed on the substrate 100. However, the disclosure is not necessarily limited thereto. In an embodiment, the fourth insulating layer 115 may include an organic material.

In the display area DA, the organic light-emitting diode OLED may be disposed on the fifth insulating layer 116. The organic light-emitting diode OLED may include a pixel electrode 211, an emission layer 212, and an opposite electrode 213. The pixel electrode 211 may be reflective of light or transmissive of light. For example, the pixel electrode 211 may include a metal.

The pixel electrode 211 may be connected to the connection electrode CM through a contact hole formed in the fifth insulating layer 116. Through this, the pixel electrode 211 may be connected to the thin-film transistor TFT.

In the display area DA, a sixth insulating layer 117 may be disposed on the fifth insulating layer 116. An opening that exposes at least a portion of the upper surface of the pixel electrode 211 may be defined in the sixth insulating layer 117. For example, the sixth insulating layer 117 may include an organic material.

In the display area DA, a spacer 119 may be disposed on the sixth insulating layer 117. For example, the spacer 119 may include an organic material. The spacer 119 may maintain a gap between the encapsulation layer 300 and the substrate 100.

The emission layer 212 may be disposed on the pixel electrode 211. The emission layer 212 may be disposed in an opening formed in the sixth insulating layer 117. In an embodiment, the emission layer 212 may have a multilayer structure including a hole injection layer, a hole transport layer, an organic emission layer, an electron transport layer, and an electron injection layer. The organic emission layer may include a light-emitting material.

The opposite electrode 213 may cover the emission layer 212 and may be disposed on the sixth insulating layer 117. In an embodiment, the opposite electrode 213 may have light-transmitting or reflective properties. For example, the opposite electrode 213 may include a metal. The opposite electrode 213 may be continuously disposed on the substrate 100.

The encapsulation layer 300 may prevent moisture and oxygen from penetrating into the organic light-emitting diode OLED from the ambient environment. For example, the encapsulation layer 300 may include a first inorganic encapsulation layer 310, an organic encapsulation layer 320, and a second inorganic encapsulation layer 330.

The first inorganic encapsulation layer 310 may be disposed on the opposite electrode 213. The organic encapsulation layer 320 may be disposed on the first inorganic encapsulation layer 310 and may have a substantially flat upper surface without generating a step around the first inorganic encapsulation layer 310. The second inorganic encapsulation layer 330 may be disposed on the organic encapsulation layer 320.

The organic encapsulation layer 320 may be disposed in the display area DA and a portion of the non-display area NDA. The first inorganic encapsulation layer 310 and the second inorganic encapsulation layer 330 may extend from the display area DA to the non-display area NDA.

A touch layer 400 may be disposed on the display panel DP. The touch layer 400 may include a first touch electrode 430, a second touch electrode 440, a first touch insulating layer 410, and a second touch insulating layer 420.

The first touch insulating layer 410 may be disposed on the encapsulation layer 300. The first touch insulating layer 410 may include silicon oxide, silicon nitride, silicon oxynitride, etc. These may be used alone or in combination with one another. The first touch insulating layer 410 may extend from the display area DA to the non-display area NDA.

The first touch electrode 430 may be disposed on the first touch insulating layer 410. In an embodiment, the first touch electrode 430 may be disposed in a non-emission area. For example, the first touch electrode 430 may overlap the sixth insulating layer 117. The first touch electrode 430 may include a metal, an alloy, a conductive metal oxide, a transparent conductive material, etc.

The second touch insulating layer 420 may cover the first touch electrode 430. The second touch insulating layer 420 may include an inorganic insulating material. The second touch insulating layer 420 may include silicon oxide, silicon nitride, silicon oxynitride, etc. These materials may be used alone or in combination with one another. A contact hole exposing a portion of the first touch electrode 430 may be defined in the second touch insulating layer 420.

The second touch electrode 440 may be disposed on the second touch insulating layer 420 and may overlap the first touch electrode 430. For example, the second touch electrode 440 may be disposed in the non-emission area of the display device 10. The second touch electrode 440 may be electrically connected to the first touch electrode 430 through the contact hole exposing a portion of the first touch electrode 430. The second touch electrode 440 may include a metal, an alloy, a conductive metal oxide, a transparent conductive material, etc.

The first touch electrode 430 and the second touch electrode 440 may form a touch electrode. In an embodiment, the touch electrode may have a mesh structure in a plan view. However, the disclosure is not necessarily limited thereto, and the structure of the touch electrode may vary.

The light blocker BM may be disposed on the second touch insulating layer 420. In an embodiment, the light blocker BM may overlap the entire non-emission area and may have a grid shape in a plan view. For example, the light blocker BM may overlap the sixth insulating layer 117 and the touch electrode. In an embodiment, the light blocker BM may cover the second touch electrode 440.

The light blocker BM may absorb external light. Accordingly, the light blocker BM may reduce the external light reflectance of the display device 10. The light blocker BM may include at least one of carbon black, black pigment, and black dye. These may be used alone or in combination with each other.

In an embodiment, the light blocker BM may define a plurality of openings that expose a portion of the second touch insulating layer 420. For example, the light blocker BM may define an opening corresponding to the organic light-emitting diode OLED. For example, the opening may overlap the organic light-emitting diode OLED.

In an embodiment, a touch protection layer may be additionally disposed between the second touch insulating layer 420 and the light blocker BM. In this case, the second touch electrode 440 may be covered by the touch protection layer. The light blocker BM may overlap the touch electrode on the touch protection layer. Examples of materials that may be used as the touch protection layer may include silicon oxide, silicon nitride, silicon oxynitride, etc. These may be used alone or in combination with each other.

The color filter CF may be disposed on the second touch insulating layer 420. When the touch protection layer is additionally disposed, the color filter CF may be disposed on the touch protection layer.

The color filter CF may be disposed in the opening defined by the light blocker BM. In an embodiment, the color filter CF may partially overlap the light blocker BM. The color of light emitted from the organic light-emitting diode OLED may be more distinctly recognized as the light passes through the color filter CF.

In an embodiment, the color filter CF may transmit light having a certain color and block light having a color other than that certain color. For example, the color filter CF may include a dye and/or pigment that absorbs light having a color other than the certain color.

A planarization layer 500 may be disposed on the light blocker BM and the color filter CF. The planarization layer 500 may cover the light blocker BM and the color filter CF. Accordingly, the reliability of the light blocker BM and the color filter CF may be increased. In an embodiment, the planarization layer 500 may have a substantially flat upper surface. Accordingly, the planarization layer 500 may compensate for a step difference of the lower surface thereof. In an embodiment, the planarization layer 500 may include an organic material. Examples of organic materials that may be used as the planarization layer 500 may include photoresist, polyacrylic resin, polyimide resin, acrylic resin, epoxy resin, acrylate resin, etc. These may be used alone or in combination with one another.

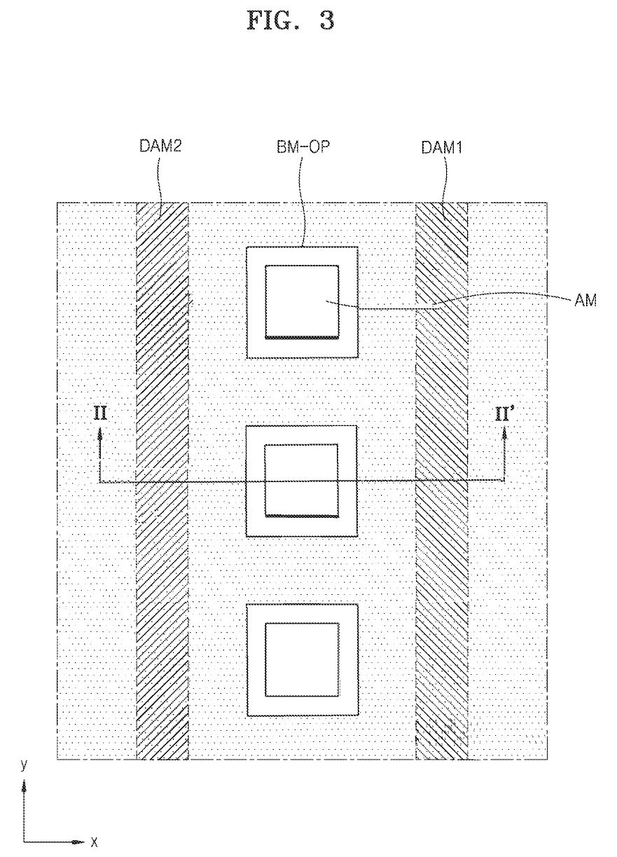

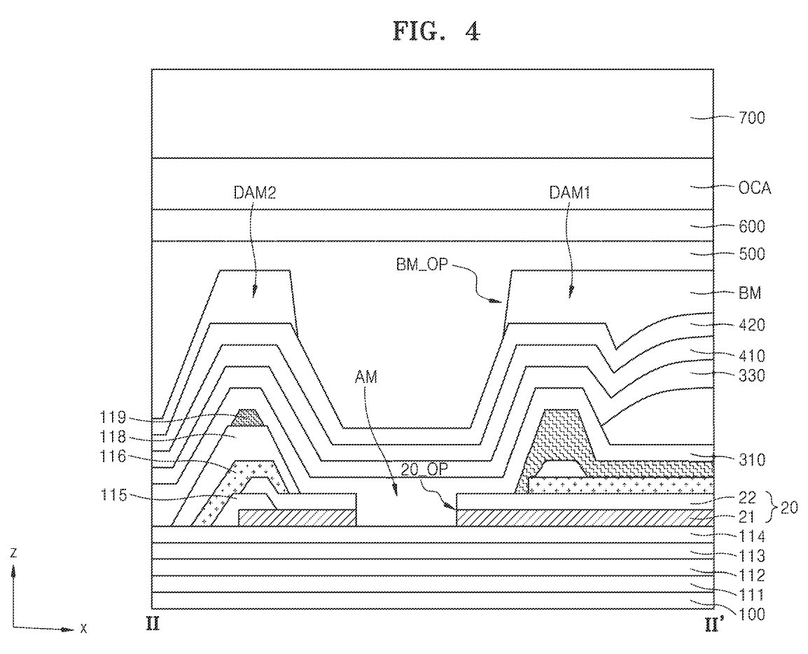

FIG. 3 is a schematic enlarged plan view of area A of FIG. 1. FIG. 4 is a schematic cross-sectional view of the display device 10 taken along line II-II' of FIG. 3.

Referring to FIGS. 3 and 4, a first dam DAM1 and a second dam DAM2 may be disposed in the non-display area NDA. The first dam DAM1 and the second dam DAM2 may each include at least portions of the insulating layers 112, 113, 114, 115, 116, 117, and 118. For example, the first dam DAM1 and the second dam DAM2 may each include an inorganic insulating material and/or an organic insulating material.

An alignment mark AM may be disposed between the first dam DAM1 and the second dam DAM2. The alignment mark AM may be provided as an opening 20_OP of a metal layer 20. For example, the alignment mark AM may be an engraved pattern provided in the metal layer 20. Specifically, the metal layer 20 may include a first metal layer 21 and a second metal layer 22 In addition, the opening 20_OP of the metal layer 20 may include an opening of the first metal layer 21 and an opening of the second metal layer 22.

As described with reference to FIG. 2, the thin-film transistor TFT including the semiconductor layer ACT, the gate electrode GE, the source electrode SE, and the drain electrode DE may be disposed in the display area DA. In the opening 20_OP of the metal layer 20 forming the alignment mark AM, the metal layer 20 may include the same material as the source electrode SE or the drain electrode DE of the thin-film transistor TFT.

The light blocker BM may be disposed on the first dam DAM1 and the second dam DAM2. The light blocker BM may have an opening BM_OP of the light blocker BM overlapping the alignment mark AM. For example, the light blocker BM may have the opening BM_OP of the light blocker BM that overlaps the opening 20_OP of the metal layer 20. The light blocker BM may be disposed on the upper surface of the first dam DAM1 and the upper surface of the second dam DAM2. As the light blocker BM includes the opening BM_OP overlapping the alignment mark AM and is disposed on the upper surface of the first dam DAM1 and the upper surface of the second dam DAM2, the visibility of the alignment mark AM may be improved.

The planarization layer 500 may be disposed on the first dam DAM1, the second dam DAM2, and the alignment mark AM. The entire upper surface of the planarization layer 500 that overlaps the alignment mark AM may be flat.

An optical function layer 600 may be disposed on the planarization layer 500. The optical function layer 600 may be a polarizing plate. However, the disclosure is not necessarily limited thereto.

In an embodiment, because the entire upper surface of the planarization layer 500 overlapping the alignment mark AM is flat, the entire upper surface of the planarization layer 500 overlapping the alignment mark AM and the entire lower surface of the optical function layer 600 may adhere to each other. For example, the entire upper surface of the planarization layer 500 overlapping the alignment mark AM and the entire lower surface of the optical function layer 600 may adhere to each other without any empty space therebetween.

As a comparative example, in order to reduce the area of a non-display area, an alignment mark may be provided as an opening in a metal layer between a first dam and a second dam. When the alignment mark is provided as an opening (for example, an engraved pattern) of the metal layer, the upper surface of a planarization layer may be concave on an area where the alignment mark is disposed, due to a step between the alignment mark and the dam. When the upper surface of the planarization layer on the alignment mark is concave, the planarization layer and the optical functional layer disposed thereon might not be bonded to each other, and thus, air bubbles may be formed between the planarization layer and the optical functional layer. When the air bubbles are formed, the alignment mark might not be visible from the outside, and thus, the quality and reliability of the display device may deteriorate.

In an embodiment, the entire upper surface of the planarization layer 500 overlapping the alignment mark AM may be flat, and thus, the entire upper surface of the planarization layer 500 overlapping the alignment mark AM and the entire lower surface of the optical functional layer 600 disposed on the planarization layer 500 may adhere to each other without any empty space therebetween. The planarization layer 500 overlapping the alignment mark AM and the optical function layer 600 may adhere to each other so that no air bubbles are formed therebetween, and the external visibility of the alignment mark AM of the engraved pattern may be increased, and thus, the quality and reliability of the display device 10 may be increased.

An adhesive OCA may be placed on the optical function layer 600, and a cover window 700 may be placed on the adhesive OCA.

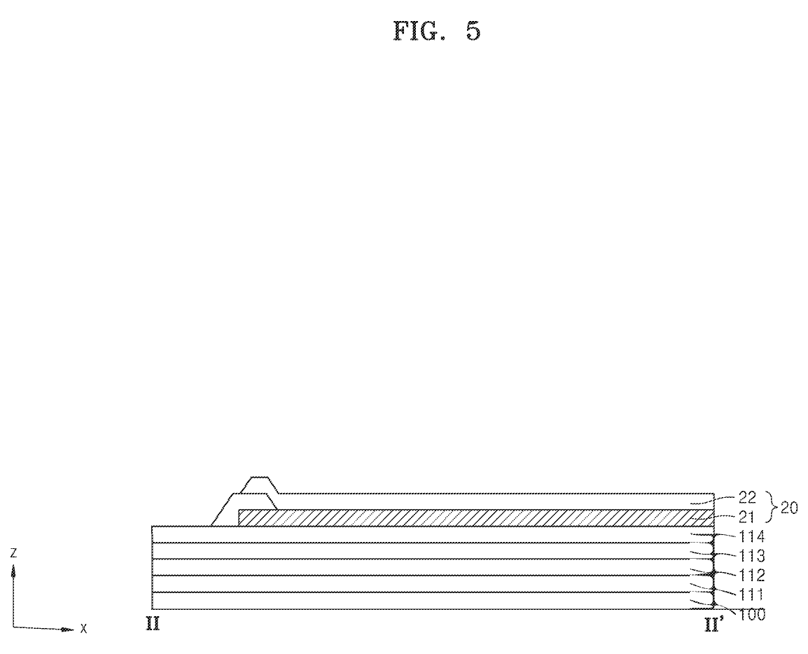

FIGS. 5 to 11 are schematic cross-sectional views illustrating a method of manufacturing a display device.

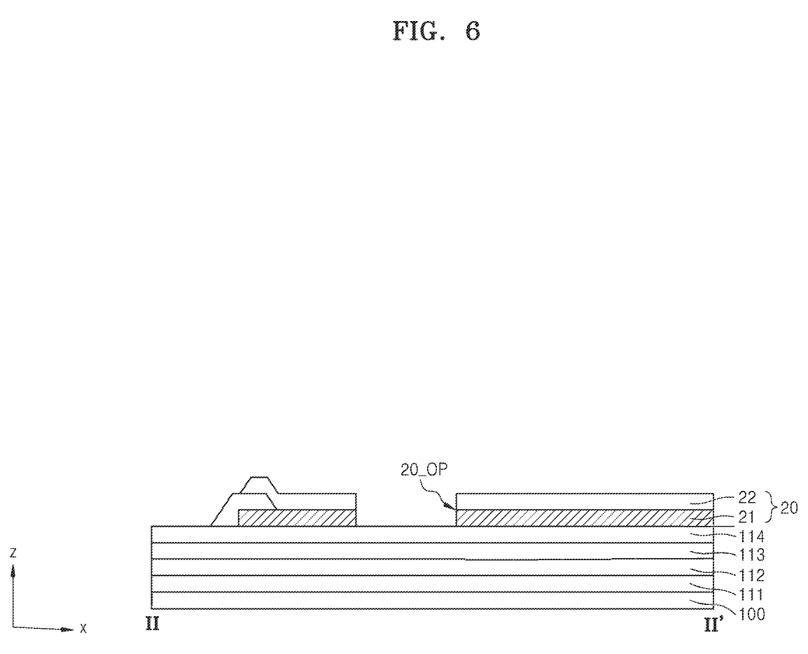

Referring to FIGS. 5 and 6, a metal layer 20 may be formed on a substrate 100. The metal layer 20 may include a first metal layer 21 and a second metal layer 22. The first metal layer 21 may include the same material as the source electrode SE (see FIG. 2) or the drain electrode DE (see FIG. 2) included in the thin-film transistor TFT (see FIG. 2) formed in the display area DA.

In an embodiment, an opening 20_OP may be formed in the metal layer 20. The opening 20_OP of the metal layer 20 may include an opening of the first metal layer 21 and an opening of the second metal layer 22. An alignment mark AM may be formed by forming the opening 20_OP in the metal layer 20. For example, the alignment mark AM may be provided as the opening 20_OP of the metal layer 20.

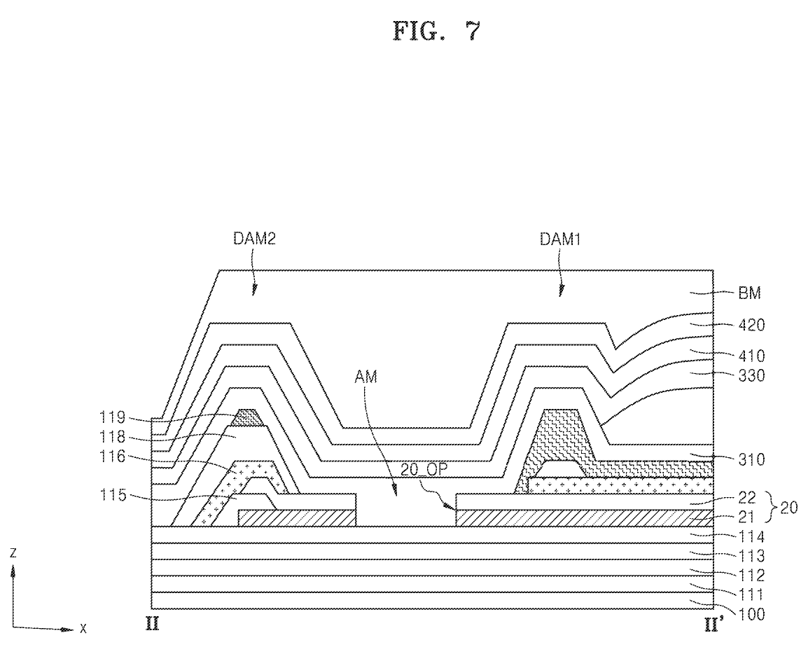

Referring to FIG. 7, a first dam DAM1 and a second dam DAM2 may be formed with the alignment mark AM therebetween. The first dam DAM1 and the second dam DAM2 may each include an organic insulating material and/or an inorganic insulating material.

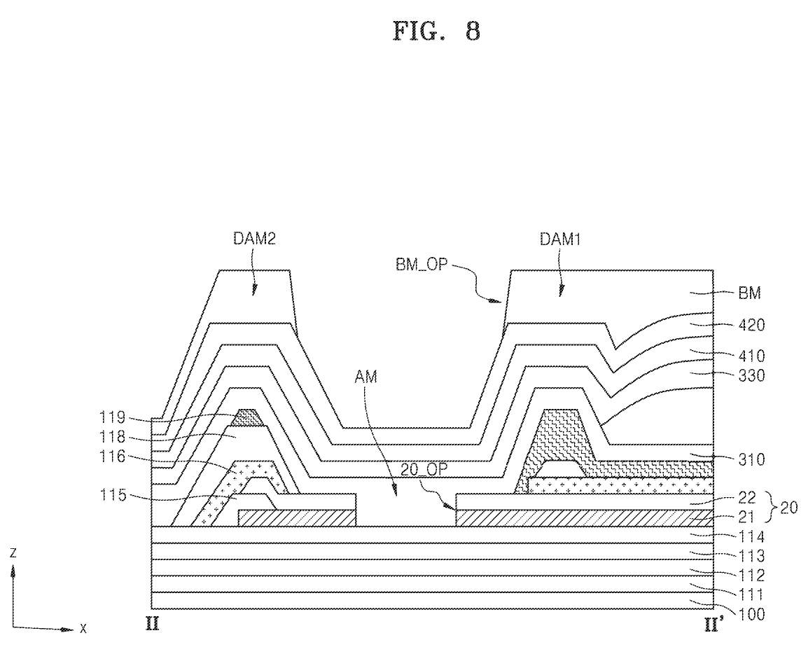

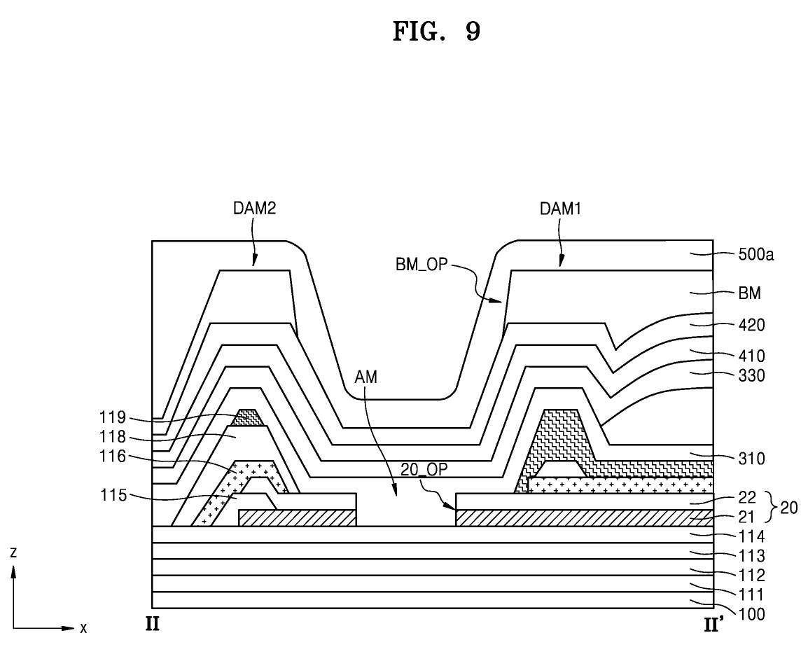

Referring to FIGS. 8 and 9, a light blocker BM may be formed on the first dam DAM1 and the second dam DAM2. An opening BM_OP overlapping the alignment mark AM may be formed on the light blocker BM. For example, the opening BM_OP overlapping the opening 20_OP of the metal layer 20 may be formed on the light blocker BM. The light blocker BM may be disposed on the upper surface of the first dam DAM1 and the upper surface of the second dam DAM2. As the light blocker BM includes the opening BM_OP overlapping the alignment mark AM and is disposed on the upper surface of the first dam DAM1 and the upper surface of the second dam DAM2, the alignment mark AM may be recognized from the outside, thereby improving the quality and reliability of the display device.

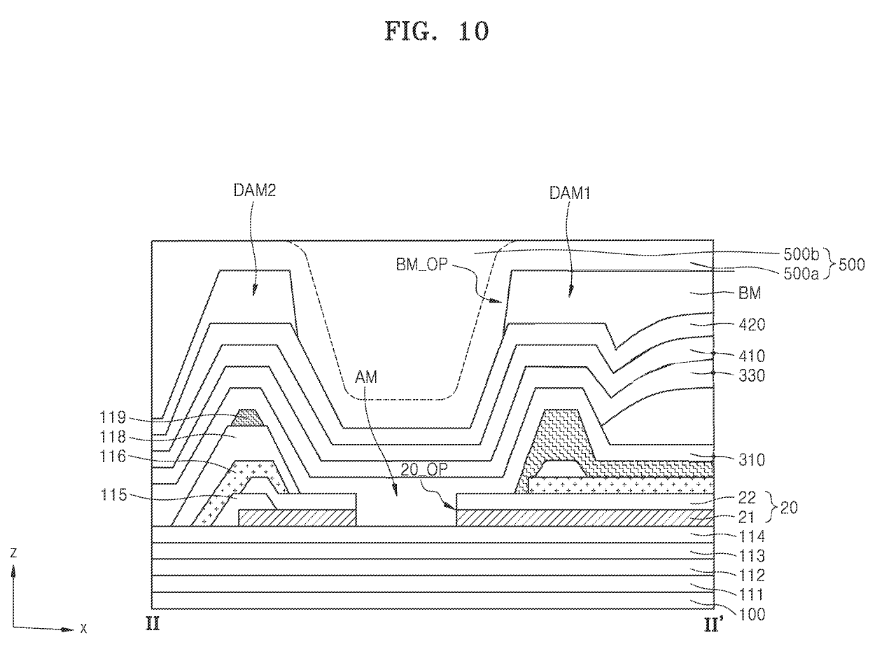

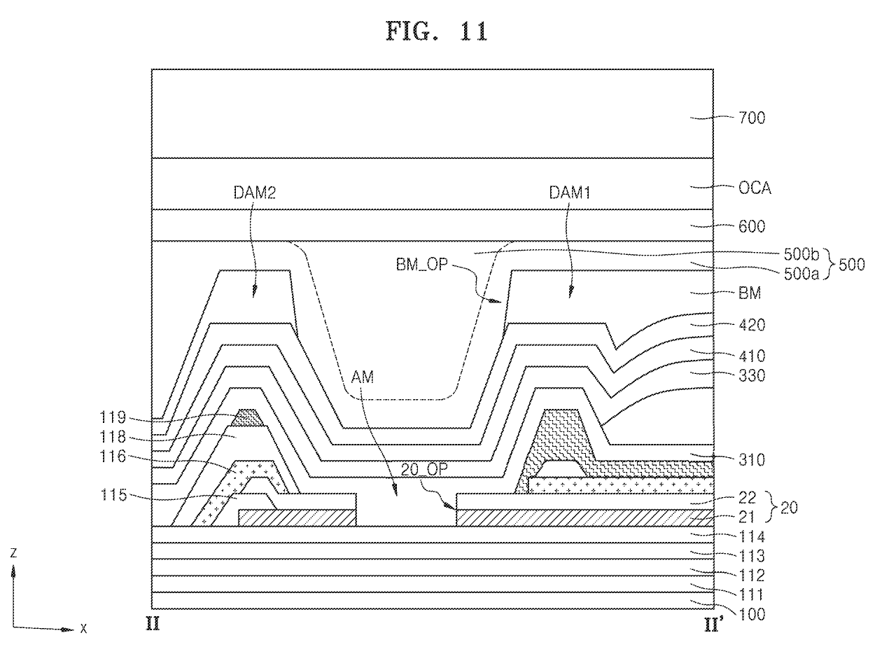

Referring to FIGS. 10 and 11, a first planarization layer 500a may be formed on the alignment mark AM and the light blocker BM. Due to the steps of the alignment mark AM and the first and second dams DAM1 and DAM2, the upper surface of the first planarization layer 500a may be concave.

A second planarization layer 500b overlapping the alignment mark AM may be formed on the first planarization layer 500a. The second planarization layer 500b may be formed on the first planarization layer 500a overlapping the alignment mark AM through a photoresist process or an inkjet process.

Because a planarization layer 500 disposed on an area overlapping the alignment mark AM is formed through a total of two processes, for example, a process of forming the first planarization layer 500a and a process of forming the second planarization layer 500b, the upper surface of the second planarization layer 500b overlapping the alignment mark AM may be flat.

Referring to FIG. 11, an optical function layer 600 may be disposed on the first planarization layer 500a and the second planarization layer 500b. As the upper surface of the second planarization layer 500b overlapping the alignment mark AM is flat, the entire upper surface of the second planarization layer 500b and the entire lower surface of the optical function layer 600 may adhere to each other. Because the second planarization layer 500b and the optical function layer 600 adhere to each other, air bubbles might not be formed therebetween, and thus, the alignment mark AM of an engraved pattern may be recognized from the outside and the quality and reliability of the display device may be increased.

An adhesive OCA may be placed on the optical function layer 600, and a cover window 700 may be placed on the adhesive OCA.

According to one or more embodiments described above, a display device with increased reliability and increased quality, and a method of manufacturing the display device may be implemented. However, the scope of the disclosure is not necessarily limited by this effect.

It should be understood that embodiments described herein should be considered in a descriptive sense and not necessarily for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure.

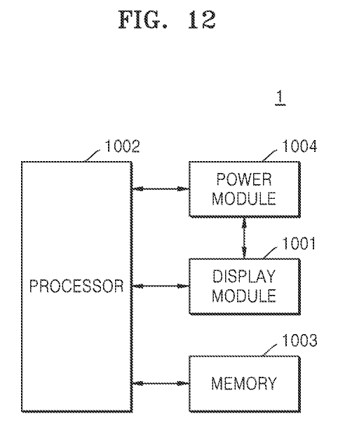

FIG. 12 is a block diagram of an electronic device according to an embodiment.

Referring to FIG. 12, a display device 1 according to an embodiment may include a display module 1001, a processor 1002, a memory 1003, and a power module 1004.

The processor 1002 may include at least one of a central processing unit (CPU), an application processor (AP), a graphic processing unit (GPU), a communication processor (CP), an image signal processor (ISP), and a controller.

Data information necessary for operation of the processor 1002 or the display module 1001 may be stored in a memory 1003. When the processor 1002 executes an application stored in the memory 1003, an image data signal and/or an input control signal is transmitted to the display module 1001, and the display module 1001 may process the received signal and output image information on a display screen.

The power module 1004 may include a power supply module, such as a power adapter or a battery device, and a power conversion module that converts power supplied by the power supply module to generate power required for the operation of the display device 1.

At least one of the components of the display device 1 may be included in the display panel according to embodiments. Additionally, some of the individual modules functionally included within a single module may be included within the display panel, while others may be provided separately from the display panel. For example, the display panel may include the display module 1001, and the processor 1002, the memory 1003, and the power module 1004 may be provided in the form of other devices within the display device 1 other than the display panel.

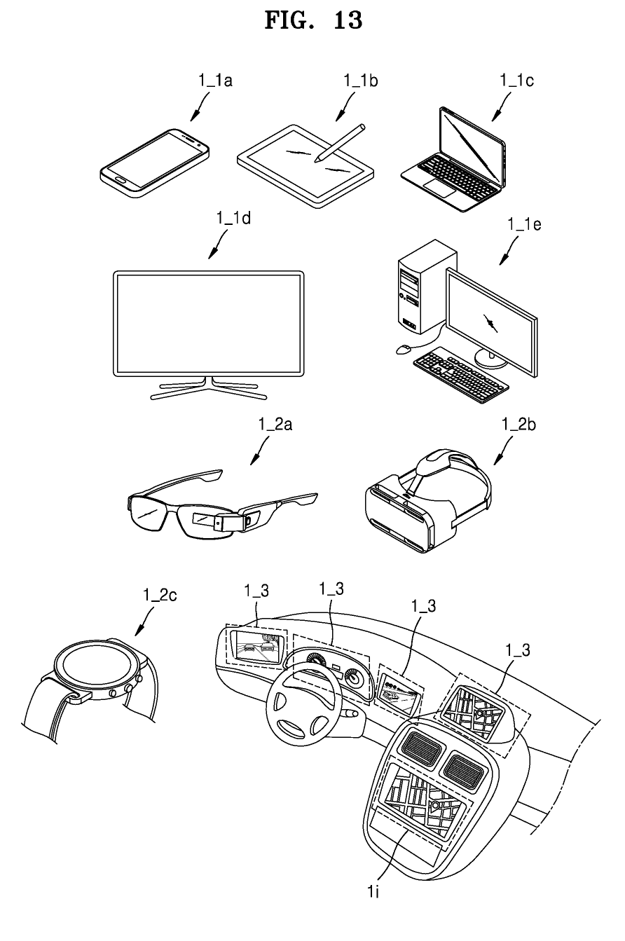

FIG. 13 is a schematic diagram of an electronic device according to various embodiments.

Referring to FIG. 13, various electronic devices to which display devices according to embodiments are applied may include not only image display electronic devices such as a smart phone 1_1a, a tablet PC 1_1b, a laptop 1_1c, a TV 1_1d, and a desk monitor 1_1e, but also wearable electronic devices including display modules such as smart glasses 1_2a, a head mounted display 1_2b, and a smart watch 1_2c, and vehicle electronic devices 1_3 including display modules such as a center information display (CID) and a room mirror display arranged on a dashboard, center fascia, and car instrument panel.

What is claimed is:

1. A display device, comprising:
a substrate including a display area and a non-display area proximate to the display area;
a first dam disposed in the non-display area;
a second dam disposed in the non-display area;
an alignment mark disposed between the first dam and the second dam and provided as an opening in a metal layer;
a planarization layer disposed on each of the first dam, the second dam, and the alignment mark; and
an optical function layer disposed on the planarization layer,
wherein an entire upper surface of the planarization layer overlapping the alignment mark is adhered to an entire lower surface of the optical function layer disposed on the planarization layer.

2. The display device of claim 1, wherein the entire upper surface of the planarization layer overlapping the alignment mark is flat.

3. The display device of claim 1, further comprising a light blocker disposed on the first dam and the second dam.

4. The display device of claim 3, wherein the light blocker includes an opening overlapping the alignment mark.

5. The display device of claim 3, wherein the light blocker includes an opening overlapping the opening of the metal layer.

6. The display device of claim 3, wherein the light blocker is disposed on an upper surface of the first dam.

7. The display device of claim 3, wherein the light blocker is disposed on an upper surface of the second dam.

8. The display device of claim 1, wherein the first dam and the second dam each include an organic insulating material and/or an inorganic insulating material.

9. The display device of claim 1, further comprising a thin-film transistor, which is disposed in the display area and includes a semiconductor layer, a gate electrode, a source electrode, and a drain electrode.

10. The display device of claim 9, wherein the source electrode or the drain electrode includes a same material as the metal layer.

11. A method of manufacturing a display device, the method comprising:
forming a metal layer on a substrate;
forming an alignment mark by forming an opening in the metal layer;
forming a first dam and a second dam on opposite sides of the alignment mark;
forming a light blocker on both the first dam and the second dam;
forming, in the light blocker, an opening overlapping the alignment mark;
forming a first planarization layer on the alignment mark and the light blocker; and
forming a second planarization layer on the first planarization layer, overlapping the alignment mark.

12. The method of claim 11, wherein at least a portion of an upper surface of the first planarization layer overlapping the alignment mark is concave.

13. The method of claim 12, wherein an upper surface of the second planarization layer overlapping the alignment mark is flat.

14. The method of claim 13, further comprising forming an optical function layer on the second planarization layer,
wherein an entire upper surface of the second planarization layer and is adhered to an entire lower surface of the optical function layer.

15. The method of claim 11, wherein the light blocker is disposed on an upper surface of the first dam.

16. The method of claim 11, wherein the light blocker is disposed on an upper surface of the second dam.

17. The method of claim 11, further comprising forming a thin-film transistor, which is disposed on the substrate and includes a semiconductor layer, a gate electrode, a source electrode, and a drain electrode.

18. The method of claim 17, wherein the source electrode or the drain electrode includes a same material as the metal layer.

19. The method of claim 11, wherein the opening of the light blocker overlaps the opening of the metal layer.

20. An electronic device, comprising:
a display panel; and
a lower cover forming an outer appearance and having an opening exposing a portion of the display panel;
the display panel comprising:
a substrate including a display area and a non-display area proximate to the display area;
a first dam disposed in the non-display area;
a second dam disposed in the non-display area;
an alignment mark disposed between the first dam and the second dam and provided as an opening in a metal layer;
a planarization layer disposed on each of the first dam, the second dam, and the alignment mark; and
an optical function layer disposed on the planarization layer,
wherein an entire upper surface of the planarization layer overlapping the alignment mark is adhered to an entire lower surface of the optical function layer disposed on the planarization layer.
